(19) United States
(12) Patent Application Publication
(10) Pub. No.: US 2007/0297129 A1
(43) Pub. Date: Dec. 27, 2007

(54) Disk device with a dual vibration-proof structure

(76) Inventors: Kuo-Hsien Liu, Taipei Hsien (TW); Yu-Shun Wen, Taipei Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/471,520

(22) Filed: Jun. 21, 2006

(51) Int. Cl. G06F 1/16; H05K 5/00

(52) U.S. Cl. 361/685

(57) ABSTRACT

A disk device with a dual vibration-proof structure comprises a body, a loader, a plurality of springs, a plurality of crash pads, and a hard disk. Two ends of the body are formed with a plurality of first fixed parts and two sides upwards extend respectively to be first sidewalls. Two sides of the loader upwards extend respectively to be second sidewalls, each of which is provided with a plurality of second parts and a plurality of holding rods. One end of the spring is connected to the corresponding first fixed part and the other end is connected to the corresponding second fixed part. One end of the crash pad is set at the first sidewall and the other end is connected to the corresponding supporting rod. The hard disk is set in the loader. Thus, the disk device with the dual vibration-proof structure is implemented.

### BACKGROUND OF THE INVENTION

1. Field of the Invention

This invention relates to a disk device and particularly to a disk device provided with a dual vibration-proof structure.

2. Description of Related Art

A conventional hard disk is generally set between the cases of a computer through a protective hard drive cover. In this case, an external force applied to the PC cases is transmitted to the hard disk and does damage to the hard disk to a certain extent.

Generally, if the hard disk is impacted with a slight force applied, a certain sector may henceforth not be accessed due to such damage; if being impacted with an intense force, the hard disk may henceforth not work and must be replaced with a new one. Thus, a hamal always handles and moves a computer for fear of damage to the hard disk that is caused by carelessness.

Indeed, from the description mentioned formerly, a further improvement is required for the formerly described conventional hard disk device obviously inconvenient and imperfect in practical use.

Consequently, because of the technical defects of described above, the applicant keeps on carving unflaggingly through wholehearted experience and research to develop the present invention, which can effectively improve the defects described above.

### SUMMARY OF THE INVENTION

It is a main object of this invention to provide a disk device provided with a dual vibration-proof structure and to locate the hard disk in a loader connected to a body with a plurality of springs and crash pads. Accordingly, when an external force impacts the body, the plurality of springs and crash pads function for dual vibration-proof effect, thereby the disk device provided with a dual vibration-proof structure being formed.

In order to achieve the objective mentioned above, this invention provides the disk device provided with the dual vibration-proof structure, comprising a body of which two ends are formed with a plurality of first fixed parts and two sides upwards extend respectively to be first sidewalls; a loader of which two sides upwards extend respectively to be second sidewalls, each of which is provided with a plurality of second parts and a plurality of holding rods; a plurality of springs of which one end is connected to the corresponding first fixed part and the other end is connected to the corresponding second fixed part; a plurality of crash pads of which one end is set at the first sidewall and the other end is connected to the corresponding supporting rod; and a hard disk that is set in the loader.

In order to further elaborate the technical means and effects adopted for the object of this invention, refer to the detailed description according to this invention accompanied with drawings; it is believed that the object, features, and points of this invention will be apparent from the description; however, the accompanied drawings are provided for reference and illustration only and not limited to this invention.

### BRIEF DESCRIPTION OF THE DRAWINGS

FIG. 1 is a 3D exploded view (1) of a disk device provided with a dual vibration-proof structure according to this invention;

FIG. 2 is a 3D exploded view (2) of the disk device provided with the dual vibration-proof structure according to this invention;

FIG. 3 is a 3D exploded view (3) of the disk device provided with the dual vibration-proof structure according to this invention;

FIG. 4 is a 3D assembly view of the disk device provided with the dual vibration-proof structure according to this invention; and

FIG. 5 is a top assembly view of the disk device provided with the dual vibration-proof structure according to this invention.

### DETAILED DESCRIPTION OF THE PREFERRED EMBODIMENTS

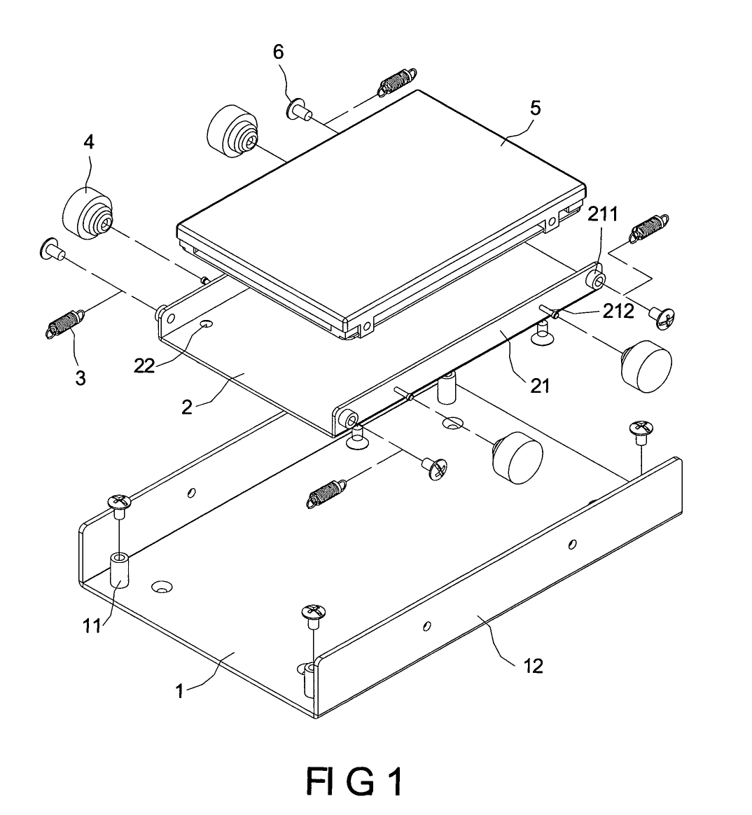

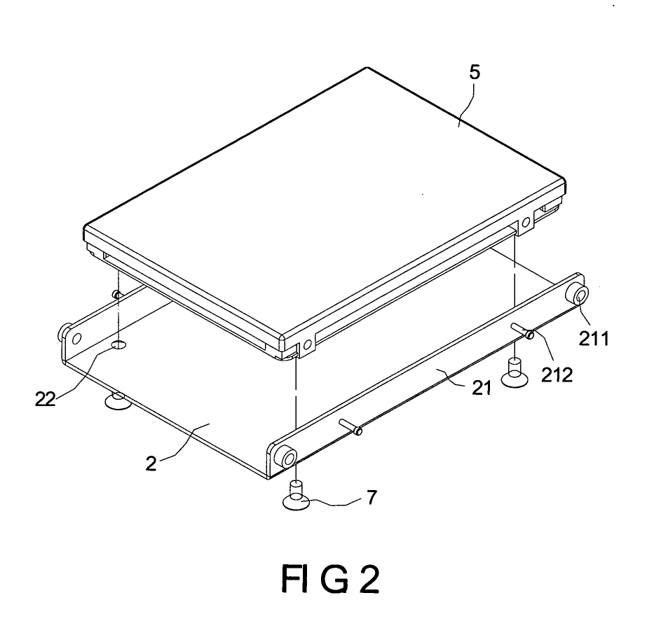

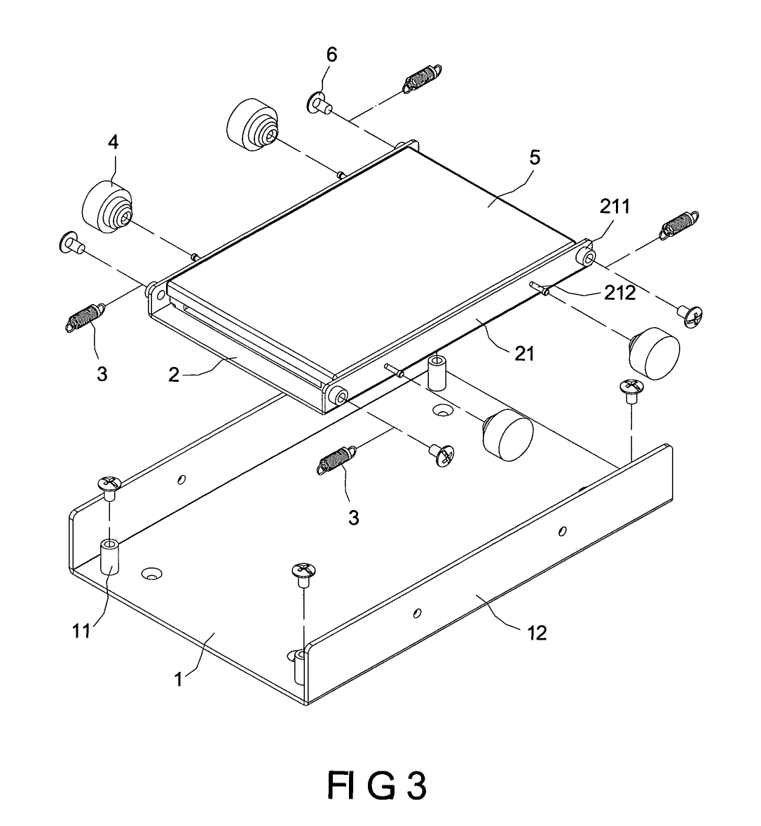

With reference to FIGS. 1 through 3, in this invention, a disk device provided with a dual vibration-proof structure, comprising a body 1, a loader 2, a plurality of springs 3, a plurality of crash pads, 4, and a hard disk 5. Two ends of the body 1 are formed with a plurality of first fixed parts 11, and two sides of the body 1 upwards extend respectively to be first sidewalls 12. Two sides of the loader 2 upwards extends respectively to be second sidewalls 21 of which the outsides are formed with a plurality of second fixed parts 211 and a plurality of holding rods 212, and the loader 2 is provided with a plurality of apertures 22.

One end of each of the plurality of springs 3 is connected to the corresponding first fixed part 11, while the other end is connected to the corresponding second fixed part 211, thereby the loader 2 being connected to the body 1. One end of each of the plurality of springs 3 is connected with a screw 6 to the corresponding first fixed part 11, while the other end is connected with a screw 6 to the corresponding second fixed part 211. However, the above-mentioned manner of connecting the spring 3 to the first fixed part 11 and the second fixed part 211 is not used to limit this invention. Further, in this invention, there are 4 springs 3, in which the amount of springs is not employed to limit this invention.

One end of each of the plurality of crash pads 4 is set inside the first sidewall 12, while the other end is connected to the corresponding supporting rod 212. The hardware 5 is connected with a screw 7 passing through the aperture 22 of the loader 2 to the loader 2. However, the manner of connecting the hard disk 5 to the loader 2 is not used to limit this invention. Besides, in this invention, there are 4 crash pads 4, in which the amount of springs is not employed to limit this invention.

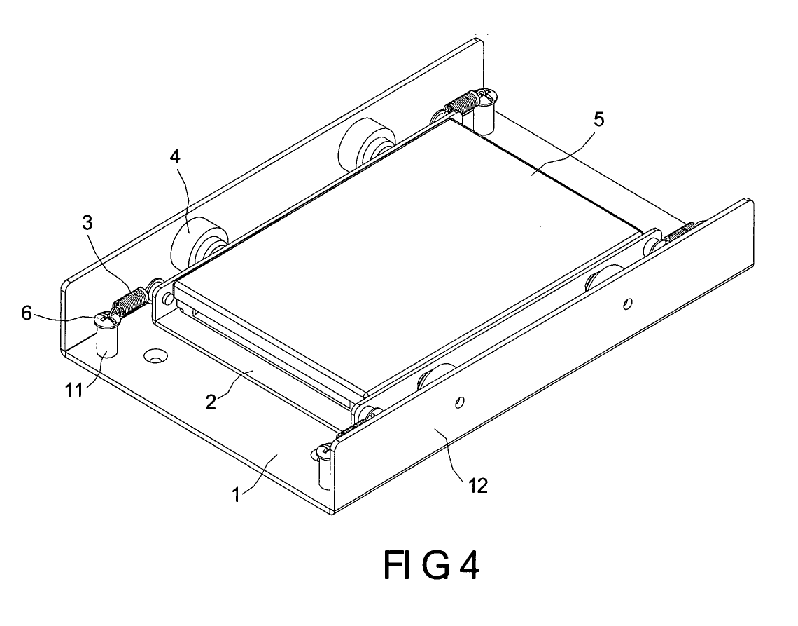

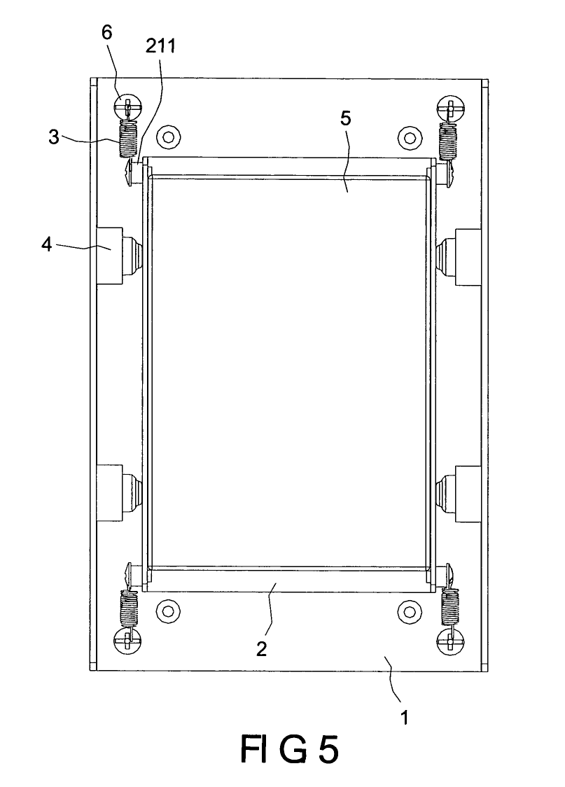

FIGS. 4 and 5 are respectively a 3D assembly view and a top assembly view of the disk device provided with the dual vibration-proof structure according to this invention. From the figures, it is apparent that the plurality of springs 3 are set between the loader 2 and the body 1 with the first fixed parts 11 and the second fixed parts 211; the plurality of crash pads 4 are also provided between the loader 2 and the body 1.

It is a main object of this invention to provide the disk device provided with the dual vibration-proof structure and to locate the hard disk 5 in the loader 2 connected to the body 1 with the plurality of springs 3 and crash pads 4. Accordingly, when an external force impacts the disk device, the plurality of springs 3 and crash pads 4 may be used to function for dual vibration-proof effect, thereby the disk device provided with the dual vibration-proof structure being implemented.

However, in the description mentioned above, only the preferred embodiments according to this invention are provided without limit to claims of this invention; all those skilled in the art without exception should include the equivalent changes and modifications as falling within the true scope and spirit of the present invention.

What is claimed is:

1. A disk device with a dual vibration-proof structure, comprising:
a body having two ends formed with a plurality of first fixed parts and two sides upwards extended respectively to be first sidewalls;
a loader having two sides upwards extended respectively to be second sidewalls, the second sidewalls provided with a plurality of second parts and a plurality of holding rods;
a plurality of springs having one end connected to the corresponding first fixed part and the other end connected to the corresponding second fixed part;
a plurality of crash pads having one end set at the first sidewall and the other end connected to the corresponding supporting rod; and
a hard disk set on the loader.

2. The disk device with the dual vibration-proof structure according to claim 1, wherein the loader is provided with a plurality of apertures.

3. The disk device with the dual vibration-proof structure according to claim 2, wherein the hardware is connected to the loader with a screw passing through the aperture of the loader.

4. The disk device with the dual vibration-proof structure according to claim 1, wherein one end of the spring is connected and fixed to the corresponding first fixed part by means of mechanism, such as a screw.

5. The disk device with the dual vibration-proof structure according to claim 1, wherein the other end of the spring is connected and fixed to the corresponding second fixed part by means of mechanism, such as a screw.

6. The disk device with the dual vibration-proof structure according to claim 1, wherein the number of the plurality of springs is four.

7. The disk device with the dual vibration-proof structure according to claim 1, wherein the number of the plurality of crash pads is four.

8. The disk device with the dual vibration-proof structure according to claim 1, wherein the plurality of second fixed parts are arranged outside the second sidewall.

9. The disk device with the dual vibration-proof structure according to claim 1, wherein the plurality of holding rods are arranged outside the second sidewall.

10. The disk device with the dual vibration-proof structure according to claim 1, wherein the plurality of crash pads are arranged outside the first sidewall.
